(19) United States
(12) Patent Application Publication
(10) Pub. No.: US 2016/0254345 A1
(43) Pub. Date: Sep. 1, 2016

(54) METAL-INSULATOR-METAL CAPACITOR ARCHITECTURE

(71) Applicant: GLOBAL FOUNDRIES Inc., Grand Cayman (KY)

(72) Inventors: Jagar SINGH, Clifton Park, NY (US); Scott BEASOR, Greenwich, NY (US)

(73) Assignee: GLOBALFOUNDRIES Inc., Grand Cayman (KY)

(21) Appl. No.: 14/634,255

(22) Filed: Feb. 27, 2015

(51) Int. Cl. H01L 49/02

(52) U.S. Cl. CPC H01L 28/56

(57) ABSTRACT

A semiconductor structure includes a semiconductor substrate, semiconductor device(s) on the substrate, and metal resistor layer(s) above the semiconductor device(s), each metal resistor layer acting as a first plate for a MIM capacitor. The structure further includes a layer of insulator material above the first plate, and metal conductor layer(s) above the insulator layer, each metal conductor layer acting as a second plate for a MIM capacitor. Fabricating the MIM capacitor uses metal and insulator used in creating electrical connections to the semiconductor device(s), saving two masks typically used to fabricate a MIM capacitor.

### BACKGROUND

1. Technical Field

The present invention generally relates to metal-insulator-metal (MIM) capacitors. More particularly, the present invention relates to MIM capacitors fabricated with semiconductor devices without using additional masks.

2. Background Information

In fabricating electrical connections to semiconductor devices, capacitors are often included in the metallization structure, for example, metal-insulator-metal (MIM) capacitors. Compared to polysilicon capacitors, MIM capacitors have higher operating frequencies, lower substrate parasitic capacitance and resistance, and potentially lower leakage current. Currently, however, fabricating MIM capacitors in the metallization structure is more complex than necessary, due to the need for two dedicated masks; one for the top plate and one for the bottom plate.

Thus, a need exists for a better architecture to include MIM capacitors in semiconductor device metallization structures.

### SUMMARY OF THE INVENTION

The shortcomings of the prior art are overcome and additional advantages are provided through the provision, in one aspect, of a method of integrating a metal-insulator-metal (MIM) capacitor in semiconductor fabrication processing. The method includes providing a starting semiconductor structure, the structure including a semiconductor substrate and one or more semiconductor devices on the substrate, and creating at least one MIM capacitor from metal and insulator used in creating electrical connections to the one or more semiconductor devices.

In accordance with another aspect, a semiconductor structure is provided. The structure includes a semiconductor substrate, one or more semiconductor devices on the substrate, and one or more metal resistor layers above the one or more semiconductor devices, at least one metal resistor layer acting as a plate for a MIM capacitor. The structure further includes a layer of insulator material above the first plate, and one or more metal conductor layers above the insulator layer, at least one metal conductor layer acting as a second plate for the MIM capacitor.

In accordance with yet another aspect, is a method. The method includes providing a starting semiconductor structure, the structure including a semiconductor substrate and one or more semiconductor devices on the substrate. The method further includes creating at least one metal-insulator-metal (MIM) capacitor from metal and insulator used in creating electrical connections to the one or more semiconductor devices. The at least one MIM capacitor includes one or more metal resistor layers above one or more semiconductor devices, at least one metal resistor layer acting as a first plate for a MIM capacitor, a layer of insulator material above the first plate, and one or more metal conductor layers above the insulator layer, at least one metal conductor layer acting as a second plate for the MIM capacitor.

These, and other objects, features and advantages of this invention will become apparent from the following detailed description of the various aspects of the invention taken in conjunction with the accompanying drawings.

### BRIEF DESCRIPTION OF THE DRAWINGS

FIG. 1 is a cross-sectional view of one example of a conventional semiconductor structure, including a metal resistor layer and metal conductor layers electrically coupled by contacts, in accordance with one or more aspects of the present invention.

FIG. 2 is a cross-sectional view of one example of a semiconductor structure according to the present invention, the structure including a semiconductor substrate with semiconductor devices thereon, a first dielectric layer, a region of dummy gate material within the dielectric layer, a second dielectric layer above the first layer and surrounding a metal resistor layer, two metal conductor layers above the second dielectric layer, one of which acts as a top plate of a metal-insulator-metal (MIM) capacitor, and the other connected by two contacts to the region of dummy gate material, in accordance with one or more aspects of the present invention.

FIG. 3 is a cross-sectional view of another example of a semiconductor structure of the present invention, a variation on the right side of FIG. 2. The structure includes layers similar to that of FIG. 2, except that the second layer of dielectric material takes the form of a high-k dielectric, and the MIM capacitor is surrounded by a dielectric material, in accordance with one or more aspects of the present invention.

FIGS. 4-6 depict one example of creating the semiconductor structure of FIG. 3, in accordance with one or more aspects of the present invention.

FIG. 7 is a cross-sectional view of another example of a MIM capacitor in accordance with one or more aspects of the present invention, the capacitor including a metal resistor layer acting as a bottom plate, a layer of high-k dielectric above the metal resistor layer, a seed barrier layer above the high-k dielectric layer, and a metal conductor layer above the seed barrier layer, in accordance with one or more aspects of the present invention.

FIG. 8 depicts one example of a variation to the structure of FIG. 7, the variation including an extended metal resistor layer and high-k dielectric layer, and a metal layer between the metal contact and the seed barrier layer, the extended metal resistor layer electrically coupled to another metal contact adjacent the one acting as a plate by a conductive interconnect through the high-k layer, the another metal contact acting as the other plate of the MIM capacitor, in accordance with one or more aspects of the present invention.

### DETAILED DESCRIPTION OF THE INVENTION

Aspects of the present invention and certain features, advantages, and details thereof, are explained more fully below with reference to the non-limiting examples illustrated in the accompanying drawings. Descriptions of well-known materials, fabrication tools, processing techniques, etc., are omitted so as not to unnecessarily obscure the invention in detail. It should be understood, however, that the detailed description and the specific examples, while indicating aspects of the invention, are given by way of illustration only, and are not by way of limitation. Various substitutions, modifications, additions, and/or arrangements, within the spirit and/or scope of the underlying inventive concepts will be apparent to those skilled in the art from this disclosure.

Approximating language, as used herein throughout the specification and claims, may be applied to modify any quantitative representation that could permissibly vary without resulting in a change in the basic function to which it is related. Accordingly, a value modified by a term or terms, such as “about,” is not limited to the precise value specified. In some instances, the approximating language may correspond to the precision of an instrument for measuring the value.

The terminology used herein is for the purpose of describing particular examples only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include (and any form of include, such as “includes” and “including”), and “contain” (and any form of contain, such as “contains” and “containing”) are open-ended linking verbs. As a result, a method or device that “comprises,” “has,” “includes” or “contains” one or more steps or elements possesses those one or more steps or elements, but is not limited to possessing only those one or more steps or elements. Likewise, a step of a method or an element of a device that “comprises,” “has,” “includes” or “contains” one or more features possesses those one or more features, but is not limited to possessing only those one or more features. Furthermore, a device or structure that is configured in a certain way is configured in at least that way, but may also be configured in ways that are not listed.

As used herein, the term “connected,” when used to refer to two physical elements, means a direct connection between the two physical elements. The term “coupled,” however, can mean a direct connection or a connection through one or more intermediary elements.

As used herein, the terms “may” and “may be” indicate a possibility of an occurrence within a set of circumstances; a possession of a specified property, characteristic or function; and/or qualify another verb by expressing one or more of an ability, capability, or possibility associated with the qualified verb. Accordingly, usage of “may” and “may be” indicates that a modified term is apparently appropriate, capable, or suitable for an indicated capacity, function, or usage, while taking into account that in some circumstances the modified term may sometimes not be appropriate, capable or suitable. For example, in some circumstances, an event or capacity can be expected, while in other circumstances the event or capacity cannot occur—this distinction is captured by the terms “may” and “may be.”

Reference is made below to the drawings, which are not drawn to scale for ease of understanding, wherein the same reference numbers are used throughout different figures to designate the same or similar components.

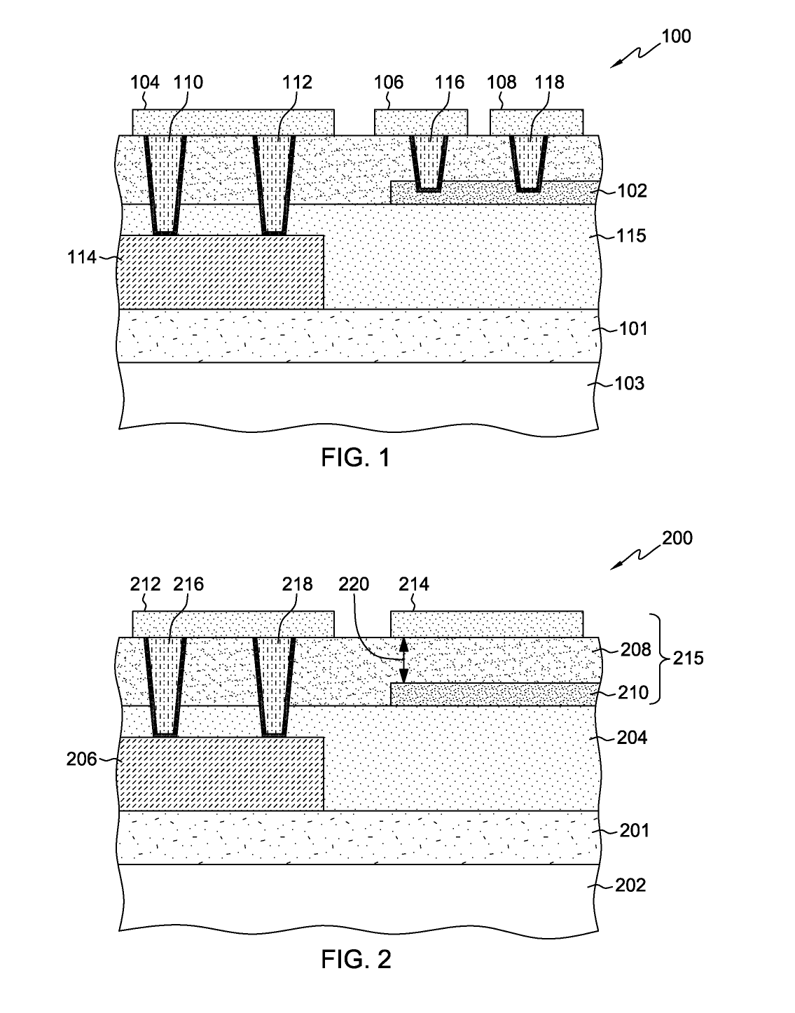

FIG. 1 is a cross-sectional view of one example of a portion 100 of a conventional semiconductor structure providing electrical connections to underlying device layer 101 on semiconductor substrate 103, including a metal resistor layer 102 and metal conductor layers 104, 106 and 108 electrically coupled by contacts, in accordance with one or more aspects of the present invention.

Contacts 110 and 112 electrically connect metal conductor layer 104 to a region 114 of polysilicon within a layer 115 of oxide, while contacts 116 and 118 electrically connect metal conductor layers 106 and 108, respectively, to metal resistor layer 102.

FIG. 2 is a cross-sectional view of one example of a semiconductor structure 200 at the “Back-End-Of-The-Line (BEOL),” according to the present invention, the structure including a semiconductor substrate 202 with one or more semiconductor devices on device layer 201 thereon, a first dielectric layer 204, a region 206 of dummy gate material within the dielectric layer, a second dielectric layer 208 above the first layer and surrounding a metal resistor layer 210, two metal conductor layers (212 and 214, e.g., made of copper) above the second dielectric layer, one of which acts as a top plate of a metal-insulator-metal (MIM) capacitor 215 (e.g., metal conductor layer 214), and the other (e.g., metal conductor layer 212) connected by two contacts (216 and 218) to the region of dummy gate material, in accordance with one or more aspects of the present invention.

Thus, the present invention uses metal and insulator already used in fabricating electrical connections to the devices, to act as a MIM capacitor. This eliminates the need for masks to fabricate the capacitor, which lowers the overall cost of making the semiconductor devices.

The semiconductor structure with MIM capacitor may be conventionally fabricated, for example, using known processes and techniques. However, although only a portion of the structure is shown for simplicity, it will be understood that, in practice, many such structures are typically included on the same bulk substrate.

Further, although examples herein show implementation of the MIM capacitor of the invention at the first metal conductor stage of metallization, it will understood that other stages of metallization could instead or in addition be used.

In one example, substrate 202 may include any silicon-containing substrate including, but not limited to, silicon (Si), single crystal silicon, polycrystalline Si, amorphous Si, silicon-on-nothing (SON), silicon-on-insulator (SOI) or silicon-on-replacement insulator (SRI) or silicon germanium substrates and the like. Substrate 102 may in addition or instead include various isolations, dopings and/or device features. The substrate may include other suitable elementary semiconductors, such as, for example, germanium (Ge) in crystal, a compound semiconductor, such as silicon carbide (SiC), gallium arsenide (GaAs), gallium phosphide (GaP), indium phosphide (InP), indium arsenide (InAs), and/or indium antimonide (InSb) or combinations thereof; an alloy semiconductor including GaAsP, AlInAs, GaInAs, GaInP, or GaInAsP or combinations thereof.

Although a planar structure is shown, the present invention is also applicable to non-planar semiconductor devices having at least one raised semiconductor structure (raised with respect to the substrate). In one example, the raised structures may take the form of a “fin.” The raised structure(s) may be etched from a bulk substrate, and may include, for example, any of the materials listed above with respect to the substrate. Further, some or all of the raised structure(s) may include added impurities (e.g., by doping), making them n-type or p-type. The non-planar structure may further include other substructures, such as, for example, a gate structure surrounding a portion of one or more of the raised structures.

In one aspect, a thickness 220 of second dielectric layer 208 can be chosen to optimize capacitor density and voltage for the application. The thinner the thickness, the higher the capacitor density, with high density achievable; conversely, the thicker the thickness, the higher the voltage. Thus, there is a direct trade-off between capacitor density and voltage. Further, a location for the MIM capacitor or capacitors in the overall metallization structure can also be optimized.

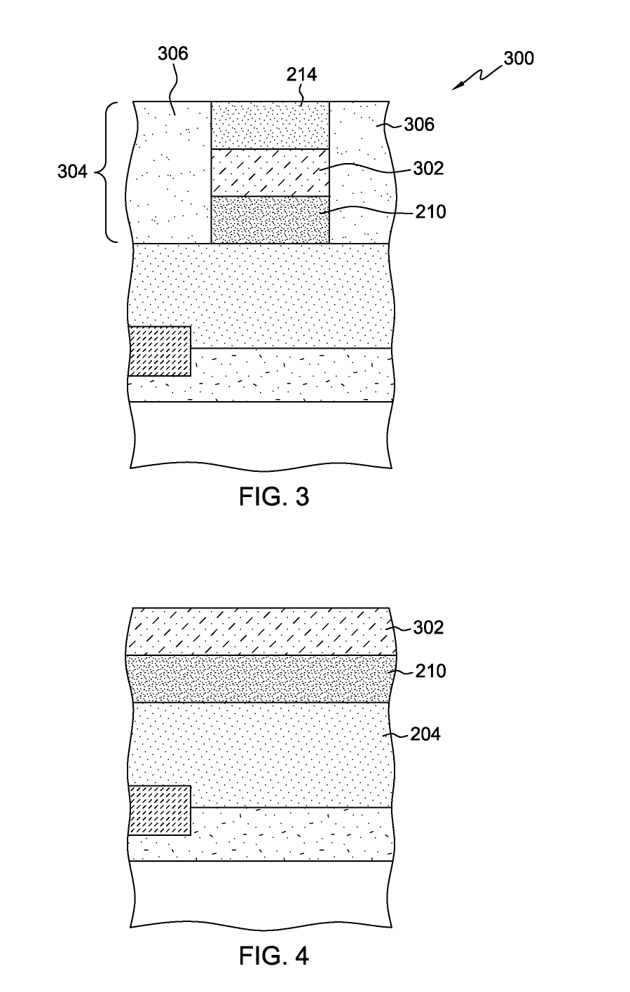

FIG. 3 is a cross-sectional view of another example of a MIM capacitor portion 300 of a semiconductor structure according to the present invention. FIG. 3 shows a variation on the right side of FIG. 2. The structure includes layers similar to that of FIG. 2, except that the second layer 302 of dielectric material takes the form of a high-k dielectric (i.e., a dielectric with a dielectric constant of more than 3.9), and the MIM capacitor 304 is surrounded by a dielectric material 306, in accordance with one or more aspects of the present invention.

FIGS. 4-6 depict one example of creating the semiconductor structure of FIG. 3, in accordance with one or more aspects of the present invention.

In FIG. 4, one example of the starting structure (prior to fabricating metal conductor layers 212 and 214 and contacts 216 and 218 in FIG. 2), substitutes a layer 302 of high-k dielectric in place of second dielectric layer 208 above metal resistor layer 210 in FIG. 2. Layer 302 can be created using conventional processes and techniques, for example, conventional deposition and lithography.

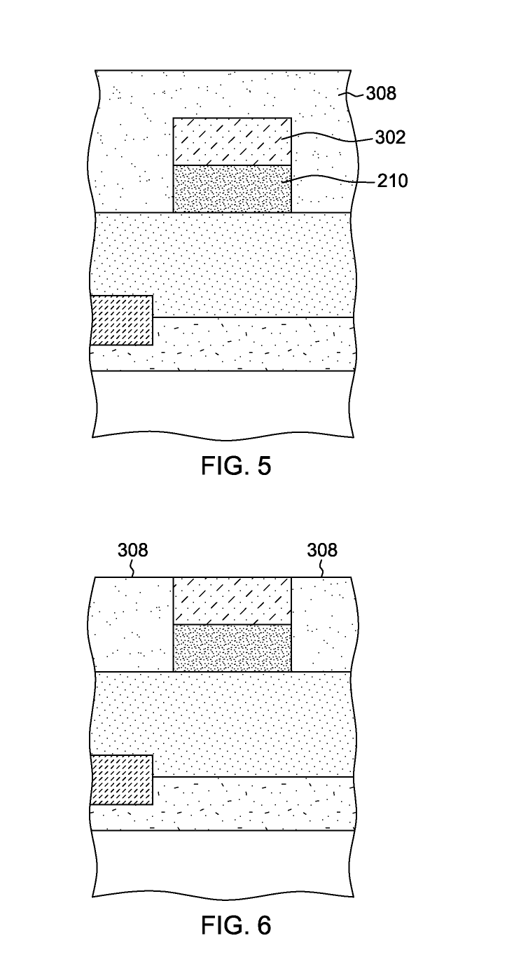

FIG. 5 depicts one example of the structure of FIG. 4 after creating a blanket conformal layer 308 of dielectric material (e.g., silicon dioxide) encompassing metal resistor layer 210 and high-k dielectric layer 302. The dielectric layer may be created, for example, using plasma-enhanced chemical vapor deposition (PECVD). The dielectric layer may then be planarized, as shown in FIG. 6, using, for example, a chemical-mechanical polishing process.

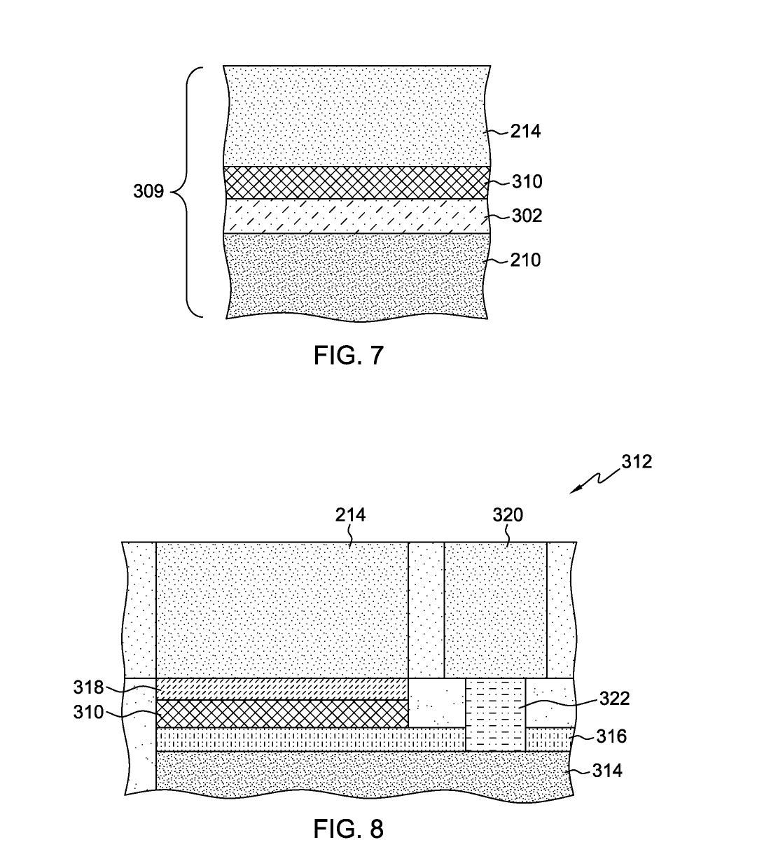

FIG. 7 is a cross-sectional view of another example of a MIM capacitor 309 in accordance with one or more aspects of the present invention, the capacitor including a metal resistor layer 210 acting as a bottom plate, a layer 302 of high-k dielectric above the metal resistor layer, a seed barrier layer 310 above the high-k dielectric layer, and a metal conductor layer 214 above the seed barrier layer, in accordance with one or more aspects of the present invention.

In one specific example, the seed barrier layer 310 of MIM capacitor 309 may include two layers of work function material, for example, a bottom layer of tantalum nitride (TaN), which may have a thickness of, for example, about 30 Angstroms to about 80 Angstroms, and a top layer of tantalum (Ta), which may have a thickness of, for example, about 30 Angstroms. Metal resistor layer 210 may include, for example, tungsten silicon (WSi), and may have a thickness of, for example, about 180 Angstroms. High-k dielectric layer 302 may include, for example, hafnium aluminum oxide (HfAlO), and may have a thickness of, for example, about 60 Angstroms. Metal conductor layer 214 may include, for example, copper.

FIG. 8 depicts one example of a variation to the structure of FIG. 7, the variation MIM capacitor 312 including an extended metal resistor layer 314 and high-k dielectric layer 316, and a metal layer 318 between the metal conductor layer 214 and the seed barrier layer 310, the extended metal resistor layer electrically coupled to another metal contact 320 adjacent the one acting as a plate by a conductive interconnect 322 through the high-k layer, the another metal contact acting as the other plate of the MIM capacitor, in accordance with one or more aspects of the present invention.

The metal layer 318 may include, for example, copper, and have a thickness of, for example, about 15 Angstroms. The metal layer serves to extend metal conductor layer 214 (acting as a plate) downward to meet seed barrier layer 310.

In a first aspect, disclosed above is a method of integrating a MIM capacitor in semiconductor fabrication processing. The method includes providing a starting semiconductor structure, the structure including a semiconductor substrate and semiconductor device(s) on the substrate, and creating MIM capacitor(s) from metal and insulator already used in creating electrical connection(s) to the semiconductor device(s).

In one example, the metal may include, for example, a metal resistor layer and a metal conductor layer, and the insulator may be, for example, situated between the metal resistor layer and the metal conductor layer.

In one example, where the metal resistor layer and metal conductor layer are present, the insulator may include, for example, an oxide, and the method may further include, for example, predetermining a thickness of the insulator for a desired density and voltage for the MIM capacitor.

In another example, where the metal resistor layer and metal conductor layer are present, the insulator may include, for example, a high-k dielectric, and the creating may include, for example, creating the metal resistor layer, creating a layer of the high-k dielectric over the metal resistor layer, and creating the metal conductor layer over the high-k dielectric layer. In one example, the method may further include, for example, creating a seed barrier layer between the high-k layer and the metal conductor layer.

In another example, where the high-k dielectric is present, creating the at least one MIM capacitor may further include, for example, electrically coupling the metal resistor layer to another conductor in the metal conductor layer. In one example, where the metal resistor layer is electrically coupled to the another conductor, creating the MIM capacitor(s) may further include, for example, creating a seed barrier layer between the high-k dielectric layer and the metal conductor layer, and creating a layer of metal between the seed barrier layer and the metal conductor layer. In one example, the electrically coupling may further include, for example, creating a conductive interconnect between the metal resistor layer and the another conductor.

In a second aspect, disclosed above is a semiconductor structure. The structure includes a semiconductor substrate, semiconductor device(s) on the substrate, and metal resistor layer(s) above the semiconductor device(s), at least one of the metal resistor layer(s) acting as a first plate for a MIM capacitor. The structure further includes a layer of insulator material above the first plate, and metal conductor layer(s) above the insulator layer, at least one of the metal conductor layer(s) acting as a second plate for the MIM capacitor.

In one example, the insulator layer may include, for example, a layer of high-k dielectric material. In one example, the structure with high-k dielectric may further include, for example, a seed barrier layer between the second plate and the high-k layer. In one example, the second plate may include, for example, copper, the seed barrier layer may include, for example, tantalum nitride (TaN) and tantalum (Ta), the high-k dielectric layer may include, for example, Hafnium Aluminum Oxide (HfAlO), and the first plate may include, for example, tungsten silicon (WSi). In another example, the structure may further include, for example, a metal layer between the second plate and the seed barrier layer, and the metal resistor layer(s) may be, for example, electrically coupled to another metal conductor. In one example, the metal resistor(s) may include, for example, an elongated metal resistor layer, and the semiconductor structure may further include, for example, a conductive interconnect electrically coupling the elongated metal resistor layer and the another metal conductor adjacent the metal conductor layer(s).

While several aspects of the present invention have been described and depicted herein, alternative aspects may be effected by those skilled in the art to accomplish the same objectives. Accordingly, it is intended by the appended claims to cover all such alternative aspects as fall within the true spirit and scope of the invention.

1. A method, comprising:
providing a starting semiconductor structure, the structure comprising a semiconductor substrate and one or more semiconductor devices on the substrate; and
creating at least one Metal-Insulator-Metal (MIM) capacitor from metal and insulator used in creating electrical connections to the one or more semiconductor devices.

2. The method of claim 1, wherein the metal comprises a metal resistor layer and a metal conductor layer, and wherein the insulator is situated between the metal resistor layer and the metal conductor layer.

3. The method of claim 2, wherein the insulator comprises an oxide, the method further comprising predetermining a thickness of the insulator for a desired density and voltage for the MIM capacitor.

4. The method of claim 2, wherein the insulator comprises a high-k dielectric, and wherein the creating comprises:
creating the metal resistor layer;
creating a layer of the high-k dielectric over the metal resistor layer; and
creating the metal conductor layer over the high-k dielectric layer.

5. The method of claim 4, further comprising creating a seed barrier layer between the high-k dielectric layer and the metal conductor layer.

6. The method of claim 4, wherein creating the at least one MIM capacitor further comprises electrically coupling the metal resistor layer to another conductor in the metal conductor layer.

7. The method of claim 6, wherein creating the at least one MIM capacitor further comprises:
creating a seed barrier layer between the high-k dielectric layer and the metal conductor layer; and
creating a layer of metal between the seed barrier layer and the metal conductor layer.

8. The method of claim 7, wherein the electrically coupling comprises creating a conductive interconnect between the metal resistor layer and the another conductor.

9. A semiconductor structure, comprising:
a semiconductor substrate;
one or more semiconductor devices on the substrate;
one or more metal resistor layers above one or more semiconductor devices, at least one metal resistor layer acting as a first plate for a MIM capacitor;
a layer of insulator material above the first plate; and
one or more metal conductor layers above the insulator layer, at least one metal conductor layer acting as a second plate for the MIM capacitor.

10. The semiconductor structure of claim 9, wherein the insulator layer comprises a layer of one of an oxide, nitride and high-k dielectric material.

11. The semiconductor structure of claim 10, further comprising a seed barrier layer between the second plate and the insulator layer.

12. The semiconductor structure of claim 11, wherein the second plate comprises copper, wherein the seed barrier layer comprises tantalum nitride (TaN) and tantalum (Ta), wherein the insulator layer comprises Hafnium Aluminum Oxide (HfAlO), and wherein the first plate comprises tungsten silicon (WSi).

13. The semiconductor structure of claim 11, further comprising a metal layer between the second plate and the seed barrier layer.

14. The semiconductor structure of claim 13, wherein the at least one metal resistor layer is electrically coupled to another metal conductor.

15. The semiconductor structure of claim 14, wherein the at least one metal resistor layer comprises an elongated metal resistor layer, the semiconductor structure further comprising a conductive interconnect electrically coupling the elongated metal resistor layer and the another metal conductor adjacent the one or more metal conductor layers.

16. A method, comprising:
providing a starting semiconductor structure, the structure comprising a semiconductor substrate and one or more semiconductor devices on the substrate; and
creating at least one metal-insulator-metal (MIM) capacitor from metal and insulator used in creating electrical connections to the one or more semiconductor devices;
wherein the at least one MIM capacitor comprises:
one or more metal resistor layers above one or more semiconductor devices, at least one metal resistor layer acting as a first plate for a MIM capacitor;
a layer of insulator material above the first plate; and
one or more metal conductor layers above the insulator layer, at least one metal conductor layer acting as a second plate for the MIM capacitor.
